(19) United States
(12) Patent Application Publication
(10) Pub. No.: US 2009/0262509 A1
(43) Pub. Date: Oct. 22, 2009

(54) Welding Part Structure Of A Stem And A Component To Be Welded, A Semiconductor Device Which Has The Welding Part Structure, An Optical Module Which Has The Semiconductor, And The Production Method Thereof

(75) Inventors: Motoki Saji, Osaka (JP); Mitsutoshi Kamakura, Osaka (JP)

Correspondence Address: FISH & RICHARDSON P.C., P.O. BOX 1022, MINNEAPOLIS, MN, 55440-1022, US

(73) Assignee: SUMITOMO ELECTRIC INDUSTRIES, LTD., Osaka (JP)

(21) Appl. No.: 11/859,840

(22) Filed: Sep. 24, 2007

(30) Foreign Application Priority Data
Sep. 26, 2006 (JP) 2006-259863
Sep. 10, 2007 (JP) 2007-233519

(51) Int. Cl. H05K 7/00; B23P 17/00

(52) U.S. Cl. 361/809; 29/592.1

(57) ABSTRACT

A high projection is provided outside the bottom surface of a cap and a low and small protrusion is provided inside the projection. The projection is resistance-welded to a stem by allowing the projection to abut the stem so as to supply an electric current thereto. Even if melt particles flow inwardly, they are blocked by the small protrusion arranged inside so as not to enter the internal space, thereby eliminating a tapping test of an optical device and an optical module.

### BACKGROUND OF THE INVENTION

1. Field of the Invention

The present invention relates to an improvement and a manufacturing method of a projection needed when a leg of a lens holder is resistance-welded to a stem in a semiconductor device having an electron device chip, a light-emitting device chip, and a light-receiving device chip that are mounted thereon; and an optical module, such as an optical transmitter/receiver module, an optical receiver module, and an optical transmitter module.

2. Description of the Related Art

For example, in the case of a photodiode device, a photodiode (PD) chip is fixed at the center of the stem; a lead pin is connected to an electrode by wire bonding; and a cap is welded thereon. The welding is executed by YAG laser welding or the resistance welding. In the present invention, the cap is resistance-welded to the stem. In the resistance welding, an orbital protrusion is formed on the bottom of the cap, and by supplying an electric current thereto, the protrusion is melted due to resistance heating so as to fusion-bond the cap to the stem.

In the case of a semiconductor laser device, a laser diode (LD) is fixed to the pole of the stem having a pole; a monitor photodiode (MPD) is attached directly below the laser diode; the lead is connected to the electrode by wire bonding; then, the lens holder is covered thereon so as to weld it to the stem.

In the case of the optical transmitter/receiver module, the laser diode (LD), the monitor photodiode (MPD), a receiver photodiode (PD), a wavelength division multiplexing filter (WDM), and so forth are fixed to a structure on the stem; and the lens holder is covered thereon after the wire bonding.

In the case of the optical receiver module, on the photodiode fixed on the stem and accommodated in the cap, a cylindrical sleeve (lens holder) is placed and welded to the stem. In any case, in the resistance welding, the protrusion is formed on the bottom of the sleeve, and the protrusion is melted and solidified due to the heating by the supplied electric current, so that the sleeve is fixed to the stem. In even other semiconductor device chips without light acceptance, members, such as the stem, the cap, and the sleeve, may also be resistance-welded frequently.

[Patent Document 1] Japanese Unexamined Utility model Application Publication No. 5-013676

[Patent Document 2] Japanese Unexamined Patent Application Publication No. 9-205227

[Patent Document 3] Japanese Unexamined Patent Application Publication No. 10-003018

[Patent Document 4] Japanese Unexamined Patent Application Publication No. 1-205448

Patent Document 1 shows an example in that two metallic objects, without cylindrical symmetry like the cap and the stem, are welded together at one point. In a conventional dome-type projection, since the heated metallic melt sticks outside so as to be solidified, there is a problem of unattractive appearances. Then, in Patent Document 1, the center of the circular projection is tapped with a punch so as to form an inverted conical hollow. The metallic surface is heated and is melted due to its resistivity by the supplied electric current so as to flow therethrough. The liquid flows into the internal hollow so as to be solidified. The welded metal does not protrude outside. This invented content that the inverted conical hollow is provided at the center of the projection is different from that of the present invention. The external shape is quite different and the effect also differs. In the longitudinal sectional view provided herein for confirmation, the shape is fairly alike; however, please do not confuse about them.

In Patent Document 2, when the cap of the laser diode is resistance-welded to the stem, welding particles may enter the inside of the cap, so that a problem arises that it is necessary to search defective products by a tapping test. When a laser diode emitted by the supplied electric current is laterally shaken, the output light quantity is observed whether it varies. When the bead of molten metal exists inside the cap, part of the laser beam is shielded therewith so as to vary the light quantity. By the variation in light quantity, the inside presence of the bead of molten metal is detected. In Patent Document 2, the stem has a two-step structure on inside and outside while the cap also has a two-step structure on inside and outside, so that both the members are combined and welded together. Because of the combination between the hollow and the projection of the two-step, the clearances are small and bent. Even when metallic particles are produced due to welding, because of the presence of the two-step groove, the particle cannot pass through the two-step groove, preventing the particle from entering the inside. This Document is designed not to the projection but for structuring the cap/stem in two steps, so that the cap/stem structure is complicated, increasing cost.

In Patent Document 3, when the holder is resistance-welded to the stem of a laser device in the manufacturing of the laser diode module, if beads of molten metal (welding particles) are produced and remained in the holder, the laser beam is shielded by the bead, making products defective. For preventing this, the holder is divided into two upper and lower members, and the lower member is welded on the bottom surface of the stem of the laser device. The member is welded on the bottom surface, so that even the bead is produced, it does not come into the upper side. However, the lower member needs to be welded to an intermediate member, so that the number of members is increased, raising cost. Since the welding is two-step, there is also a disadvantage of taking a lot of effort. There is also a possibility that the bead of molten metal is produced in the welding between the lower member and the intermediate member so that the bead enters the inside of the holder, generating a new defective.

Patent Document 4 proposes a stem having separated projections with the same height doubly on inside and outside. Furthermore, the stem is provided with a step and has a structure in that the welding surface is lowered lower than the chip mounting surface. The height of the double projections is the same and when the projections on inside and outside are melted and airborne droplets fly inside, the droplets are to be headed off by the step. The step is essential and the structure is complicated.

In the resistance welding between the cap and the stem of the laser diode, between the cap and the stem of the photodiode, between the holder and the stem of the optical transmitter/receiver module having these diodes built therein, or between the cap and the stem of other semiconductor device chips, even when the projection is melted due to the heating by the supplied electric current so that part of the melt becomes dispersed particles, to prevent these particles from entering the inside of the cap and holder is an object of the present invention.

When two members are resistance-welded together, a small projection with a tapered shape is provided on the welding surface so as to weld the member by melting it. When the two members are brought into contact with each other and a voltage is applied thereto, an electric current flows through the contact surface. While the sectional area of other regions is large and the resistance is small, the sectional area of the projection is small and the resistance is large, so that the projection is heated. Since the projection is tapered, an end portion is especially heated. Part of the projection is melted due to the heating from the end, so that the projection loses firmness and is crushed. FIG. 1 shows a middle stage of the welding for fabricating a conventional optical device; FIG. 2 is a sectional view showing a state after the welding.

On a stem 3, an optical device (LD, LED, and PD) chip 20 is fixed. The stem 3 is provided with the appropriate number of lead pins 26, 27, and 28 attached thereto. On the lower bottom surface 5 of a cap 2, a protrusion 7 is provided. This is a protrusion for welding and is called a projection. When an electric current is supplied between the cap 2 and the stem 3, the protrusion 7 is strongly heated due to the large resistance of the protrusion 7. Thereby, the end of the protrusion 7 is melted so that the melt flows inside and outside.

The melt flows away toward the periphery of the protrusion. The target stem is partly melted. When the electric current is stopped, the metallic melt is solidified because of the heating stop. Thereby, the two members are fusion-bonded together. The substance produced meanwhile is the continuously flowing melt. If the heating is rapid or the pressure is excessive, part of the melt may separate therefrom so as to splash. This becomes a dispersed particle W called as a welding particle, an airborne droplet, or a bead of molten metal. The welding flow may splash inside so as to enter internal spaces of the cap, the holder, and the sleeve. This is a problem.

The remaining of micro dispersed particles within a hermetic space is inconvenient especially in the case of an optical device and an optical module. In the case of the laser diode and a laser module, the welding particles may block the optical path so that the light of the laser diode may insufficiently come out. In the case of the photodiode and a photo detector module, the welding flow may block the optical path so that the external light may not arrive at the photodiode.

Thus, it has been necessary to check if the welding particle remains within internal spaces of the cap, the sleeve, and the holder.

In the case of the laser diode, while the light emitted by supplying an electric current between electrodes so as to emit the laser diode is being monitored by monitoring the backward light of the laser diode with the photo detector, a laser diode device is vibrated. FIG. 2 shows the situation. When the welding particle W blocks the optical path, the light quantity is reduced. When the welding particle W is separated from the optical path, the light quantity is increased. The light quantity varies in such a manner, so that the remaining of the welding particle can be detected. The device is tapped, so that it is called a tapping test. When the dispersed particle (the welding particle) exists and the package is shaken, it is not always that the welding particle comes just on the optical path. Even if the light quantity is not varied by the shaking for a predetermined time, we cannot say that no welding particle exists. In order to eliminate test omissions, the test must be performed for a long time, so that the tapping test increases the cost of the device.

### SUMMARY OF THE INVENTION

A welding part structure of a stem and a cap according to the present invention includes a projection formed outside and a small protrusion formed inside the projection on the bottom surface of a cap flange. The height Q of the projection is higher than that S of the small protrusion. Q>S. It is simple to form the projection and the small protrusion in concentric with each other; however, being concentric is not an essential requirement. The projection has a trapezoidal section with a broad bottom and a narrow end.

The outer wall of the projection may be sloped; alternatively, the inner wall may be sloped; and both the outer and inner walls may also be sloped. The small protrusion may have a trapezoidal section, a rectangular section, or an inverted trapezoidal section. The projection is the same as a normal projection for resistance welding. Accordingly, according to the present invention, the small protrusion is additionally provided on the inside of the normal projection.

When the bottom surface of the cap and the stem are put together and an electric current is supplied, the outside projection is brought into contact with the stem so as to melt due to resistance heating by the supplied electric current. If airborne droplets produced by the welding might fly inside, they are blocked by the small protrusion so as not to enter the internal space of the cap. When the projection has a sloped outer wall and a vertical inner wall the melt during the welding is difficult to flow inside, so that the blocking is more effective.

In the manufacturing of an optical module, a problem arises even if airborne droplets fly outside. In order to prevent the flowing outside, the small protrusion may be provided also outside; a cap groove-like depression may be formed on the (flange) bottom surface of the cap; or a stem groove-like depression may be formed on the upper surface of the stem. The outward melt, droplets, and airborne droplets are caught by the small protrusion, the cap groove-like depression, or the stem groove-like depression arranged outside so as not to come outside. When the projection has a sloped inner wall and a vertical outer wall, the melt during the welding is difficult to flow outside, so that the blocking is more effective. On the bottom surface of the small protrusion, an insulation film may also be formed. Even when the resistance welding is started, the electric current does not flow due to the insulation film, so that the small protrusion is not melted. The molten height of the projection depends on the small protrusion, so that the molten amount of the resistance welding can be easily managed.

A semiconductor device and an optical module having the welding part structure according to the present invention and the use of the manufacturing method of a semiconductor device or an optical module according to the present invention reduce airborne droplets (welding particles) entering the internal space of the cap or the lens holder so as to stabilize electric and optical characteristics, eliminating the tapping test.

Since the small protrusion and the projection are provided on the cap bottom surface doubly on inside and outside, even if airborne droplets fly due to the melting of the projection, they are blocked by the small protrusion so that the airborne droplets do not enter the inside of the cap. There is no possibility that welding particles enter the inside of the cap, preventing defective products due to the dispersed particle from being generated. This also eliminates the time-consuming tapping test. Since the small protrusion does not melt to remain solid, welding allowances between the cap and the stem are uniform, preventing the size dispersion.

### BRIEF DESCRIPTION OF THE DRAWINGS

FIG. 1 is a sectional view showing a state that a cap having a conventional onefold projection is fusion bonded to a stem having an optical device and an electronic device by pressing the cap formed on the bottom surface of the projection onto the stem to supply an electric current to between the step and the cap so that part of the projection is heated and melted due to the resistance heating;

FIG. 2 is a longitudinal sectional view of the cap and the stem showing a state of the cap with the conventional projection that has been resistance-welded to the stem;

FIG. 3 is a sectional view of a cap according to a first embodiment of the present invention and having a small protrusion formed inside and a projection formed outside;

FIG. 4 is a bottom view of the cap according to the first embodiment of the present invention and having the small protrusion formed inside and the projection formed outside;

FIG. 5 is a partial sectional view of a bottom portion of the cap according to the first embodiment of the present invention and having the small protrusion formed inside and the projection formed outside;

FIG. 6 is a longitudinal sectional view showing an intermediate state when the cap according to the first embodiment of the present invention and having the small protrusion formed inside and the projection formed outside is resistance-welded to the stem;

FIG. 7 is a partial sectional view of a cap according to a second embodiment of the present invention and having a small protrusion formed inside and a projection formed outside;

FIG. 8 is a longitudinal sectional view showing an intermediate state when the cap according to the second embodiment of the present invention and having the small protrusion formed inside and the projection formed outside is resistance-welded to the stem;

FIG. 9 is a partial sectional view of a cap according to a third embodiment of the present invention and having a small protrusion formed inside and a projection formed outside;

FIG. 10 is a longitudinal sectional view showing an intermediate state when the cap according to the third embodiment of the present invention and having the small protrusion formed inside and the projection formed outside is resistance-welded to the stem;

FIG. 11 is a partial sectional view of a cap according to a fourth embodiment of the present invention and having a small protrusion formed inside and a projection formed outside;

FIG. 12 is a longitudinal sectional view showing an intermediate state when the cap according to the fourth embodiment of the present invention and having the small protrusion formed inside and the projection formed outside is resistance-welded to the stem;

FIG. 13 is a partial sectional view of a cap according to a fifth embodiment of the present invention and having a small protrusion formed inside and a projection formed outside;

FIG. 14 is a longitudinal sectional view showing an intermediate state when the cap according to the fifth embodiment of the present invention and having the small protrusion formed inside and the projection formed outside is resistance-welded to the stem;

FIG. 15 is a partial sectional view of a cap according to a sixth embodiment of the present invention and having a small protrusion formed inside and a projection formed outside wherein the entire surfaces of the small protrusion and the inner wall of the projection are covered with an insulation film;

FIG. 16 is a longitudinal sectional view showing a state that the cap according to the sixth embodiment of the present invention and having the small protrusion formed inside and the projection formed outside wherein the entire surfaces of the small protrusion and the inner wall of the projection are covered with the insulation film is resistance-welded to the stem;

FIG. 17 is a partial sectional view of a cap according to a seventh embodiment of the present invention and having a small protrusion formed inside and a projection formed outside wherein the entire surfaces of the small protrusion and the inner wall of the projection are covered with an insulation film;

FIG. 18 is a longitudinal sectional view showing a state that the cap according to the seventh embodiment of the present invention and having the small protrusion formed inside and the projection formed outside wherein the entire surfaces of the small protrusion and the inner wall of the projection are covered with the insulation film is resistance-welded to the stem;

FIG. 19 is a partial sectional view of a cap according to an eighth embodiment of the present invention and having a small protrusion formed inside and a projection formed outside wherein the entire surfaces of the small protrusion and the inner and outer walls of the projection are covered with an insulation film; and

FIG. 20 is a longitudinal sectional view showing a state that the cap according to the eighth embodiment of the present invention and having the small protrusion formed inside and the projection formed outside wherein the entire surfaces of the small protrusion and the inner and outer walls of the projection are covered with the insulation film is resistance-welded to the stem.

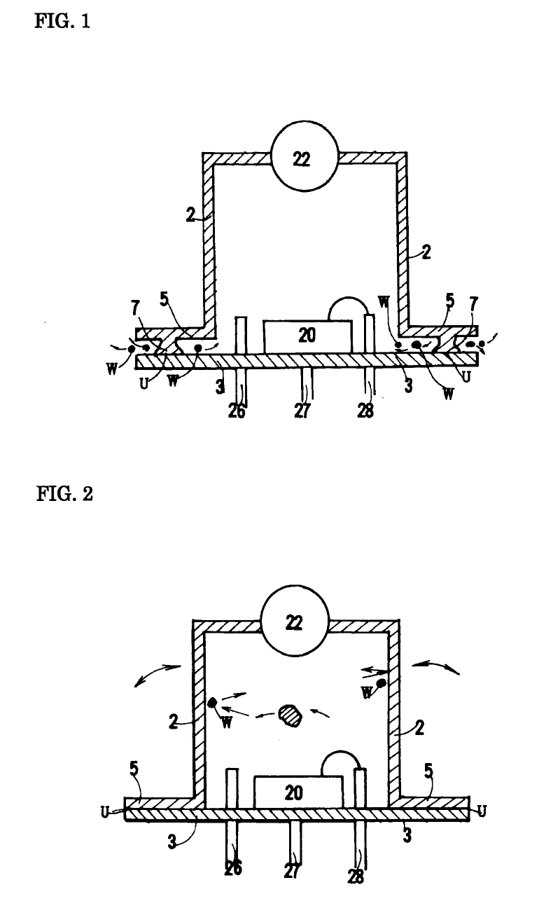

### DESCRIPTION OF THE PREFERRED EMBODIMENTS

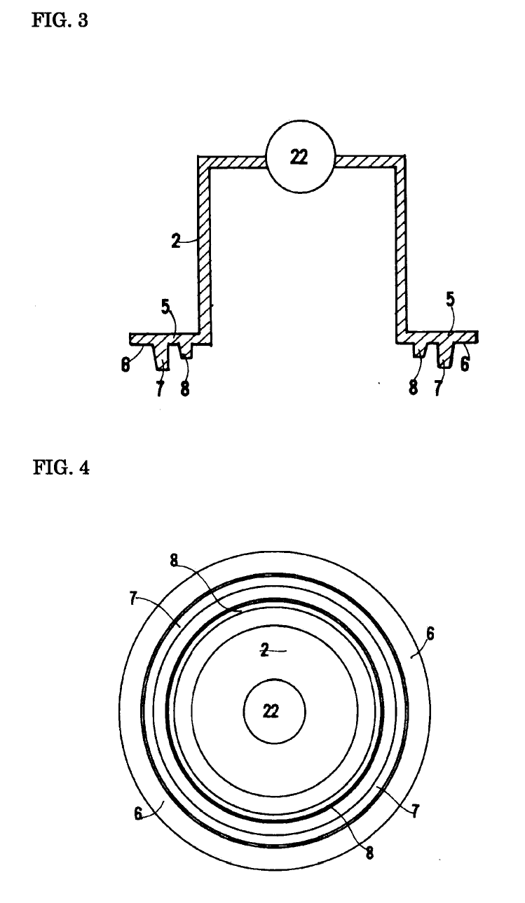

### First Embodiment

[Example 1 (FIGS. 3, 4, 5, and 6) (Projection with a sloped outer wall and a vertical inner wall)]

A longitudinal sectional view of a cap having a welding part structure of a stem and the cap according to an embodiment of the present invention is shown in FIG. 3. A bottom view is shown in FIG. 4. This shows a cap 2 for a laser diode and a photodiode having a lens 22 arranged on a top; alternatively, it may also be a cap having other semiconductor device chips accommodated therein. The structure is applicable to all the devices in that the cap is attached to the stem by resistance welding. The shape of the cap 2 includes a tubular type with a broad-collar flange 5 on the bottom surface, for example. The flange 5 is provided with a welding part structure arranged on the bottom surface 6. The present invention is characterized in that the welding part structure of the stem and the cap includes a projection 7 and a small protrusion 8 provided doubly on outside and inside. The projection 7 provided on the outside is brought into contact with the stem 3 and is melted due to the resistance heating by the supplied electric current for fusion-bonding the stem, in the same way as in a conventional welding part structure. The small protrusion 8 provided on the inside is a novel devisal of the present invention.

FIG. 5 is an enlarged sectional view of part of the welding part structure. On the bottom surface 6 of the flange 5 in the cap 2, the higher projection 7 and the lower small protrusion 8 are formed. As shown in FIG. 4, these are concentric with each other. According to the present invention, being concentric is not an essential requirement. They may be arranged in any manner as long as they are doubly annular on inside and outside. As shown in FIG. 5, the bottom surface 6 has the outline efghijklmn from the outside. The external circumferential surface gf of the projection 7 is an inclined plane. The end face gh is a part which comes in contact with the stem 3 at first during welding. The internal circumferential surface ih is a vertical plane. The height of the projection 7 from the flange bottom surface 6 is assumed to be Q. The section fghi of the projection 7 is a plane with a sloped outer wall and a vertical inner wall.

The small protrusion 8 is provided more inside. The character jklm denotes the section of the small protrusion 8. The height of the small protrusion 8 is assumed to be S. Q>S. The character ki denotes the end face; however, it does not come into contact with the stem 3 at first during the welding. After the height is reduced due to the melting of the projection 7, the small protrusion 8 comes into contact with the stem 3. Between the projection 7 and the small protrusion 8, the clearance ji is provided. Characters ef and mn denote planes with the same height as that of the bottom surface 6. It is important that the projection 7 and the small protrusion 8 are provided on outside and inside with the clearance ij.

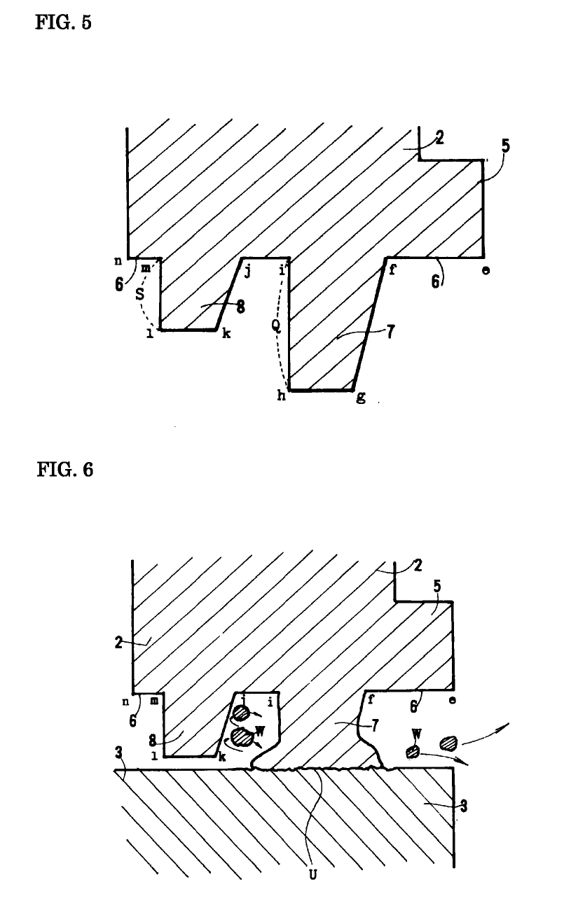

At first, a voltage is applied across both members, which are the end of the projection 7 and the stem 3, and are touching each other, so as to supply an electric current therethrough. The electric current flows through the contact part between the projection 7 and the stem 3. The sectional area of the projection 7 is narrow, so that the resistance is large. Since the projection 7 is tapered, the resistance of the end portion is large. The electric current is constant, so that the heating value is large especially at the end portion. The portion touching the stem 3 is melted due to the heating, so that the contact surface U heaves irregularly so as to be penetrated to each other. As shown in FIG. 6, the projection 7 is melted so that the melt flows outwardly and inwardly along the surface of the stem 3. Since a pressure is applied, the material of the melted projection 7 flows out toward both sides.

Because of the rapid heating, part of the material flies in a space as micro airborne droplets W. The outwardly directed airborne droplets W flow out as they are, so that they may be allowed. The inwardly flying airborne droplets W have been a problem. The inwardly directed airborne droplets W abut the outer wall jk of the small protrusion 8 arranged more inside so as to be rebounded. The airborne droplets W do not enter the inside of the cap 2 beyond the end face lk of the small protrusion 8. When the welding further proceeds from the state of FIG. 6, the inside small protrusion 8 also comes in contact with the stem 3 80 that an electric current flows from the contact surface U. In this state, the welding is stopped. The small protrusion 8 is scarcely melted so that the end face Ik sets in the intact state of being contact with the stem 3. Even when the airborne droplets W fly inwardly, they are held within the space kji and do not enter the internal space of the cap.

Even if the welding is not finished at the moment when the small protrusion 8 comes into contact so that the small protrusion 8 is also melted slightly; however, because of the small quantity of melt, the small protrusion 8 keeps fluidity and does not fly as the airborne droplets W. Hence, the splashing of airborne droplets from the small protrusion 8 is not noticed. If Q>S, the end portion of the projection 7 is only melted and the welding electric current can be stopped not to melt the small protrusion 8.

This timing is understood by the rapidly reduced resistance value due to the contact of the small protrusion 8 with the stem. When the small protrusion 8 abuts the stem 3, the resistance value is reduced, so that it can be understood by the use of a constant current circuit. Even if the cutting the current is somewhat delayed so as to melt the small protrusion 8, the airborne droplets W cannot be produced, so that it is not necessary to worry about it.

When the small protrusion 8 comes into contact with the stem 3, the deformation is finished, so that the small protrusion 8 also has the effect of accurately determining the height relationship between the cap 2 and the stem 3. S is about 200 μm to 30 μn; Q is about 300 μm to 50 μm; and Q>S.

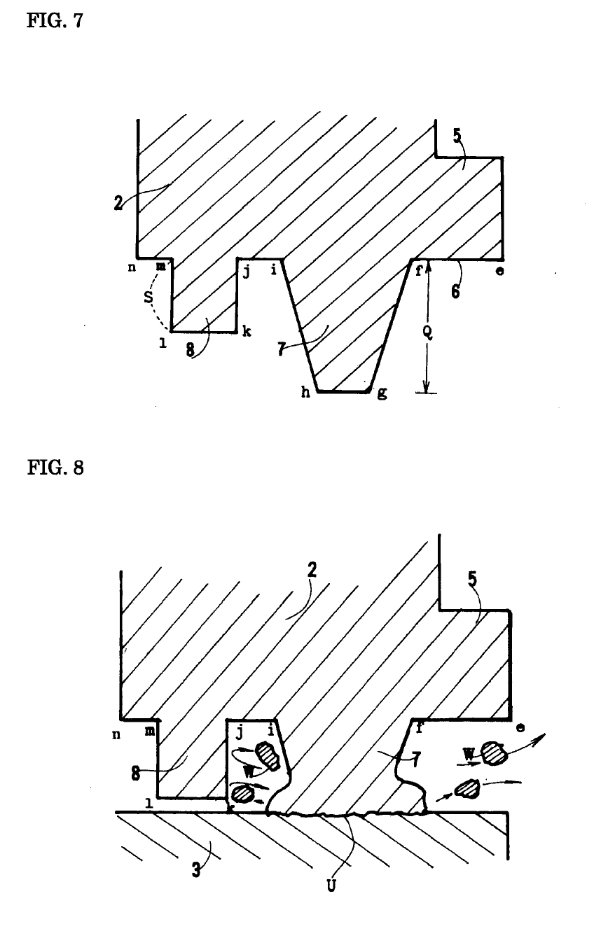

### Second Embodiment

[Example 2 (FIGS. 7 and 8) (Projection with a sloped outer wall and a sloped inner wall)]

A longitudinal sectional view of only lower part of a cap having a welding part structure of a stem and the cap according to a second embodiment of the present invention is shown in FIG. 7. On the bottom surface 6 of the flange 5 on the lower bottom of the cap 2, the projection 7 and the small protrusion 8 are formed doubly on outside and inside. The height Q of the outside projection 7 is higher than that S of the inside small protrusion 8. Between the projection 7 and the small protrusion 8, the clearance kij is provided.

The section jklm of the small protrusion 8 is rectangular. The section may be rectangular or trapezoidal. The section fghi of the projection 7 is a trapezoidal section with both sloped. sides. Example 2 is different from Example 1 in this point. When the cap 2 is resistance-welded to the stem 3 by pressing the cap 2 onto the stem 3 to supply an electric current, the end portion of the projection 7 is heated and melted due to the resistance heating so as to fusion-bond the cap 2 to the stem 3.

Even when part of the melt becomes the airborne droplets W so as to fly inside, as shown in FIG. 8, they are blocked by the inside small protrusion 8, so that the airborne droplets W do not fly inside the cap. When the end face lk of the small protrusion 8 comes into contact with the stem 3, the welding is stopped by turning off the electric current, so that the space kji is remained and the airborne droplets W are enclosed therewith.

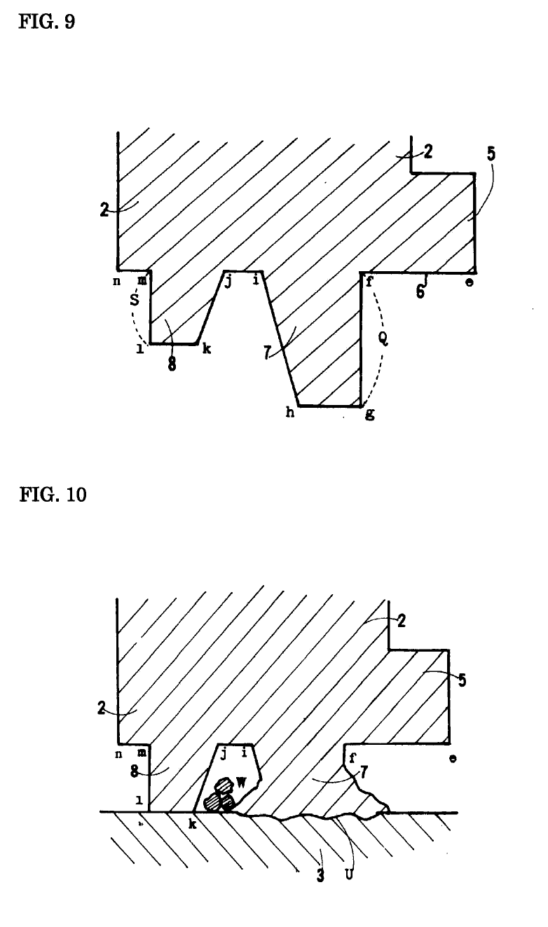

### Third Embodiment

[Example 3 (FIGS. 9 and 10) (Projection with a sloped inner wall and a vertical outer wall)]

A longitudinal sectional view of only lower part of a cap having a welding part structure of a stem and the cap according to a third embodiment of the present invention is shown in FIG. 9. It is common to doubly form the projection 7 and the small protrusion 8 on the bottom surface 6 of the flange 5 of the cap 2. The outer wall fg of the projection 7 is vertical and the inner wall hi is sloped. The small protrusion 8 has a sloped outside and a vertical inside. Example 3 is different from Examples 1 and 2 in the sectional shape of the projection 7.

The projection 7 is brought into contact with the stem 3 to supply an electric current by applying a voltage for resistance-heating the projection 7. The projection 7 melts and spreads due to the heat to be fusion-bonded to the stem 3. Even when part of the material splashes due to rapid heating and pressuring, the inward splashing is blocked by the small protrusion 8. When the small protrusion 8 comes into contact with the stem 3 as shown in FIG. 10, the welding is stopped by turning off the electric current. The airborne droplets W are enclosed within the space ijk formed between 7 and the small protrusion 8.

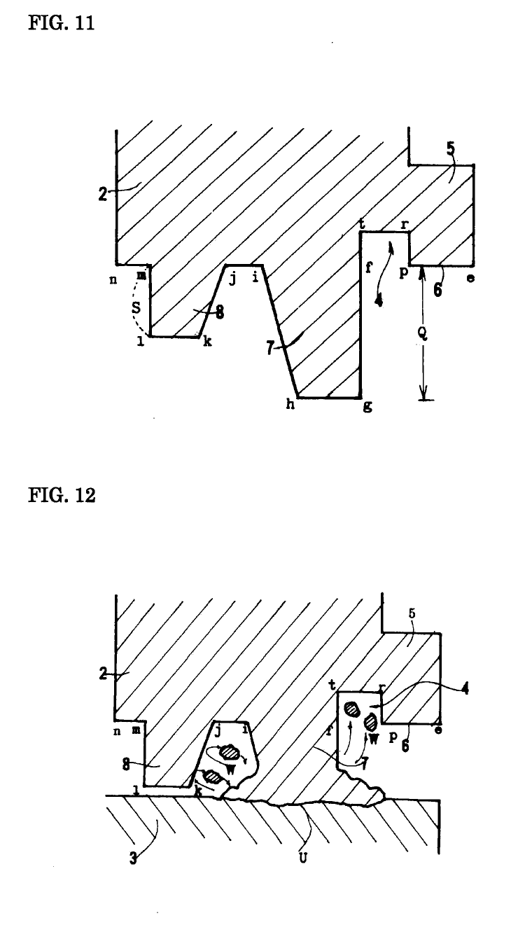

### Fourth Embodiment

[Example 4 (FIGS. 11 and 12) (Cap groove provided on the bottom surface of the cap outside the projection)]

It is common to form the projection 7 and the small protrusion 8 on the bottom surface 6 of the flange 5 of the cap 2. It is also common that the height Q of the projection 7 is higher than that S of the small protrusion 8. Q>S. On the bottom surface 6 of the flange 5 of the cap 2, a cap groove-like depression 4 is circularly formed outside the projection 7. The sectional shape of the bottom surface 6 of the flange 5 of the cap 2 is complicated like the section eprtfghijklmn. The cap groove-like depression 4 has the rectangular section prtf. The cap groove-like depression 4 may have a size capable of leading the melt flow into the groove. The approximate width of the groove tr=30 μm to 200 μm; the approximate height rp=20 μm to 200 μm.

The section of the cap groove-like depression 4 is not limited to rectangular but it may also be trapezoidal or triangular. When the projection 7 is resistance-welded by leading its end portion into contact with the stem 3 to supply an electric current, the end portion of the projection 7 melts so as to be fusion-bonded to the stem 3. Even when the airborne droplets W fly inside, they are blocked by the small protrusion 8, so that the outside going airborne droplets W do not fly inside the cap. The airborne droplets W are stopped at the cap groove-like depression 4. Since they are like fluid rather than solid particles, the airborne droplets W do not spread outside but adhere to the cap groove-like depression 4 to be solidified.

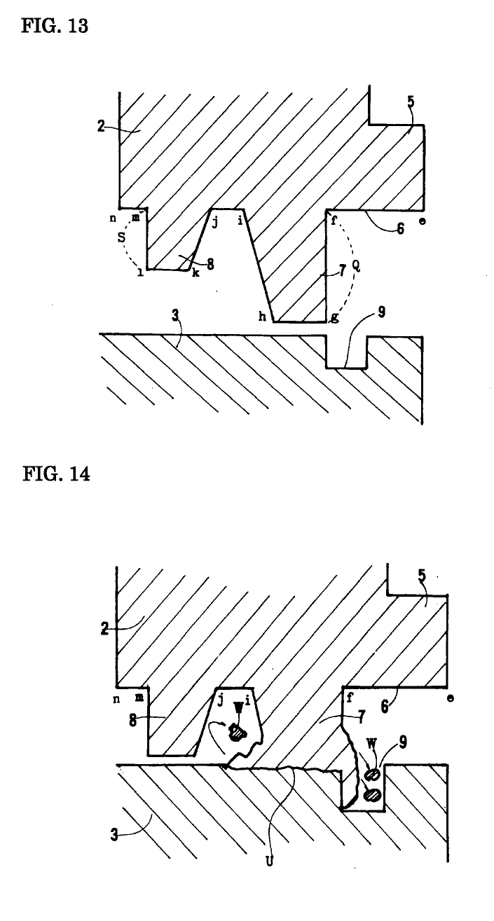

### Fifth Embodiment

[Example 5 (FIGS. 13 and 14) (Stem groove-like depression provided on the upper surface of the stem)]

FIGS. 13 and 14 show a fifth embodiment. It is common to form the projection 7 and the small protrusion 8 on the bottom surface 6 of the flange 6 of the cap 2. It is also common that the height Q of the projection 7 is higher than that S of the small protrusion 8. Q>S. On the upper surface of the stem 3, an annular stem groove-like depression 9 is formed with a diameter agreeing with the outer diameter of the projection 7. The height of the stem groove-like depression 9 is 20 μm to 200 μm; the width 30 μm to 200 μm.

Part of the projection 7 is melted so as to flow and spread inside and outside. The inward flow can be prevented by the small protrusion 8. Even when the produced airborne droplets W fly inside, they are enclosed within the space formed by the small protrusion 8. The melt flow directed outside is cut into the stem groove-like depression 9. The melt is solidified therewithin and does not come out. Even if the melt once becomes the airborne droplets W, they do not come outside because of solidification.

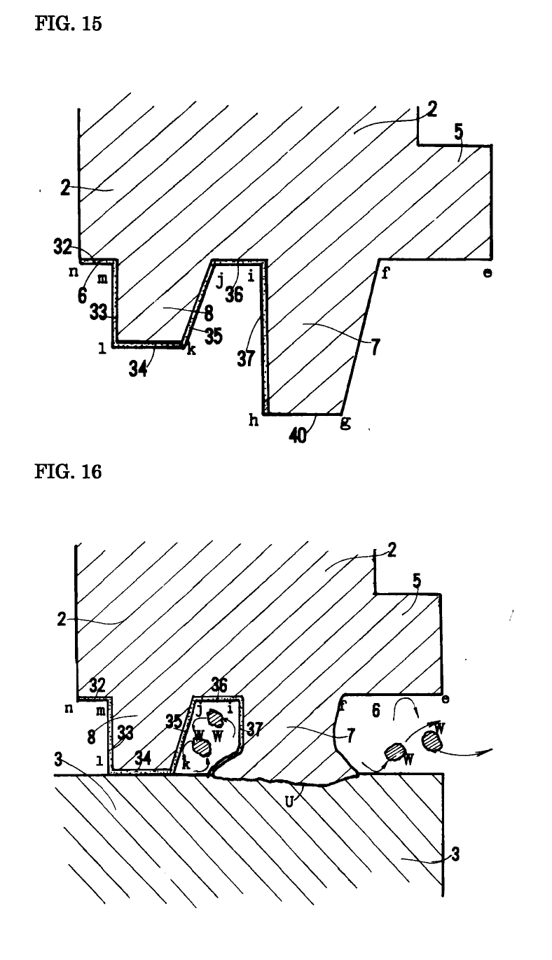

### Sixth Embodiment

[Example 6 (FIGS. 15 and 16; Insulation film formed on the entire surfaces of the small protrusion and the inner wall of the projection]

FIGS. 16 and 16 show a sixth embodiment. This is further improved from the embodiment shown in FIGS. 5 and 6. It is common to form the projection 7 and the small protrusion 8 on the bottom surface 6 of the flange 5 of the cap 2. An insulation film is formed on the inside bottom surface 6 of the flange, on the peripheral walls of the small protrusion 8, and the inner wall of the projection.

A first insulation film 32 is formed on the flange inside bottom surface 6 (nm); a second insulation film 33 on the inner wall (ml) of the small protrusion 8; a third insulation film 34 on the bottom surface (lk) of the small protrusion 8; a fourth insulation film 36 on the outer wall (kj) of the small protrusion 8; a fifth insulation film 36 on the flange bottom surface 6 (ji) in the intermediate between the small protrusion 8 and the projection 7; and a sixth insulation film 37 on the inner wall (ih) of the projection 7. The bottom surface (hg) of the projection 7 is an exposure part 40 not covered with the insulating film.

The insulation films 32 to 37 are continuous on inside and outside, so that they can be formed all at once. The insulation films 32 to 37 include films of SiO₂, Al₂O₃, and Nb₂O₅. The essential is only the insulation film 34, and the other insulation films may be provided or eliminated. An electric current is supplied by allowing the end portion of the projection 7 to abut the stem 3. Then, the electric current flows from the exposure part 40 on the bottom surface of the projection 7 so as to start the resistance welding. The end portion of the projection 7 is crushed so that the insulation film 34 on the bottom surface of the small protrusion 8 is brought into contact with the stem 3. Because of the insulation film 34, the electric current does not flow through the small protrusion 8, 80 that the small protrusion 8 does not melt. At this time, the resistance welding is completed, The molten height of the projection 7 depends on the small protrusion 8, so that the molten amount of the resistance welding can be easily managed.

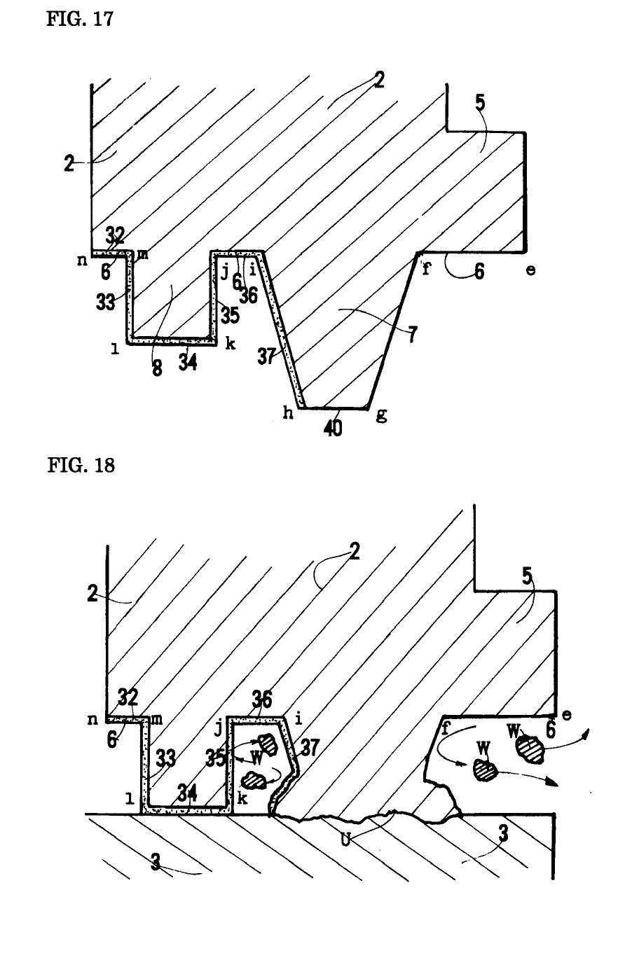

### Seventh Embodiment

[Example 7 (FIGS. 17 and 18; Insulation film formed on the entire surfaces of the small protrusion and the inner wall of the projection]

FIGS. 17 and 18 show a seventh embodiment. This is further improved from the embodiment shown in FIGS. 7 and 8. It is common to form the projection 7 and the small protrusion 8 on the bottom surface 6 of the flange 5 of the cap 2. An insulation film is formed on the inside bottom surface 6 of the flange, on the peripheral walls of the small protrusion 8, and the inner wall of the projection.

The first insulation film 32 is formed on the flange inside bottom surface 6 (nm); the second insulation film 33 on the inner wall (ml) of the small protrusion 8; the third insulation film 34 on the bottom surface (lk) of the small protrusion 8; the fourth insulation film 35 on the outer wall (kj) of the small protrusion 8; the fifth insulation film 36 on the flange bottom surface 6 (ji) in the intermediate between the small protrusion 8 and the projection 7; and the sixth insulation film 37 on the inner wall (ih) of the projection 7. The bottom surface (hg) of the projection 7 is the exposure part 40 not covered with the insulating film.

The insulation films 32 to 37 are continuous on inside and outside, so that they can be formed all at once. The insulation films 32 to 37 include films of SiO₂, Al₂O₃, and Nb₂O₅. The essential is only the insulation film 34, and the 5 other insulation films may be provided or eliminated. An electric current is supplied by allowing the end portion of the projection 7 to abut the stem 3. Then, the electric current flows from the exposure part 40 on the bottom surface of the projection 7 so as to start the resistance welding. The end portion of the projection 7 is crushed so that the insulation film 34 on the bottom surface of the small protrusion 8 is brought into contact with the stem 3. Because of the insulation film 34, the electric current does not flow through the small protrusion 8, so that the small protrusion 8 does not melt. At this time, the resistance welding is completed. The molten height of the projection 7 depends on the small protrusion 8, so that the molten amount of the resistance welding can be easily managed.

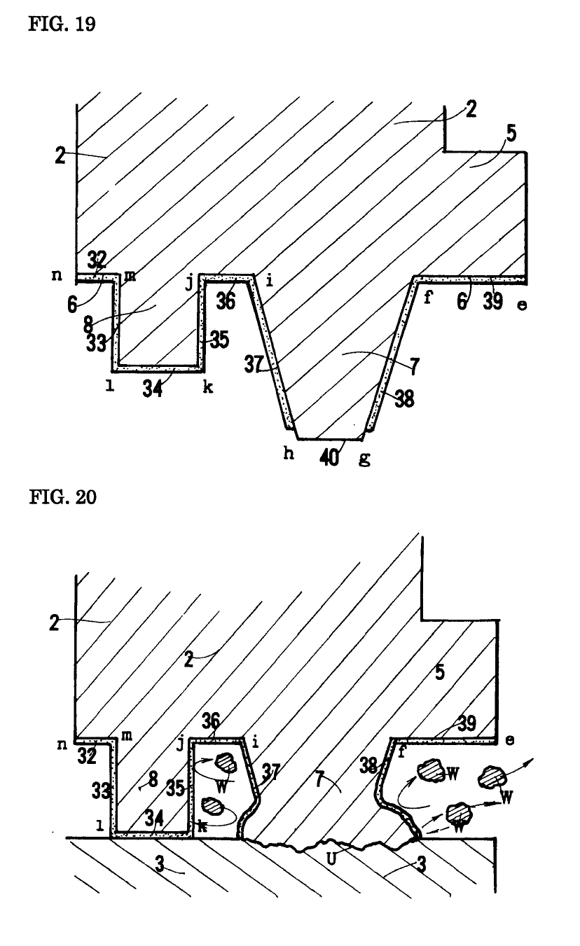

### Eighth Embodiment

[Example 8 (FIGS. 19 and 20; Insulation film formed on the entire surfaces of the small protrusion and the inner and outer walls of the projection]

FIGS. 19 and 20 show an eighth embodiment. This is further improved from the embodiment shown in FIGS. 7 and 8. It is common to form the projection 7 and the small protrusion 8 on the bottom surface 6 of the flange 5 of the cap 2. An insulation film is formed on the inside bottom surface 6 of the flange, on the peripheral walls of the small protrusion 8, and the inner and outer walls of the projection.

The first insulation film 32 is formed on the flange inside bottom surface 6 (nm); the second insulation film 33 on the inner wall (ml) of the small protrusion 8; the third insulation film 34 on the bottom surface (lk) of the small protrusion 8; the fourth insulation film 36 on the outer wall (j) of the small protrusion 8; the fifth insulation film 36 on the flange bottom surface 6 (ji) in the intermediate between the small protrusion 8 and the projection 7; and the sixth insulation film 37 on the inner wall (ih) of the projection 7; a seventh insulation film 38 on the outer wall (gf) of the projection 7; and an eighth insulation film 39 on the flange bottom surface 6 (fe). The bottom surface (hg) of the projection 7 is the exposure part 40 not covered with the insulating film. The exposure part 40 may also be made by grinding or polishing the bottom surface of the projection 7 after the insulation film is formed on the entire bottom surfaces of the flange.

The insulation films 32 to 37 are continuous on inside and outside, so that they can be formed all at once. The insulation films 32 to 39 include films of SiO₂, Al₂O₃, and Nb₂O₅. The essential is only the insulation film 34, and the other insulation films may be provided or eliminated. An electric current is supplied by allowing the end portion of the projection 7 to abut the stem 3. Then, the electric current flows from the exposure part 40 on the bottom surface of the projection 7 so as to start the resistance welding. The end portion of the projection 7 is crushed so that the insulation film 34 on the bottom surface of the small protrusion 8 is brought into contact with the stem 3. Because of the insulation film 34, the electric current does not flow through the small protrusion 8, so that the small protrusion 8 does not melt. At this time, the resistance welding is completed. The molten height of the projection 7 depends on the small protrusion 8, so that the molten amount of the resistance welding can be easily managed.

In the above-description, the embodiments and Examples according to the present invention have been described; however, the above-disclosed embodiments and Examples according to the present invention are strictly for the purposes of exemplification and the scope of the present invention is not limited to these embodiments according to the present invention. The scope of the present invention is defined by that of Claims and furthermore, the scope of the present invention includes equivalents to the Claims and the entire modifications within the scope of the Claims.

What is claimed is:

1. A welding part structure of a stem and a component to be welded, comprising:
the stem having a semiconductor device chip mounted thereon;
a high and tapered projection provided on the bottom surface of the component to be welded or the upper surface of the stem for resistance-welding the component to be welded; and
a small protrusion provided inside the projection and having a height lower than that of the projection.

2. The welding part structure according to claim 1, wherein the outer wall or the inner wall of the projection is sloped.

3. The welding part structure according to claim 1, wherein the component to be welded or the stem is provided with a groove-like depression formed on a region outside the projection.

4. A semiconductor device comprising:
a semiconductor device chip;
a stem having the semiconductor device chip mounted thereon; and
a cap arranged for surrounding the semiconductor device chip,
wherein the cap is resistance-welded to the stem using a welding part structure of the stem and the cap, the welding part structure including a high and tapered projection provided on the bottom surface of the cap or the upper surface of the stem and a small protrusion provided inside the projection and having a height lower than that of the projection.

5. The semiconductor device according to claim 4, wherein the semiconductor device chip is an optical semiconductor device chip and the cap includes a lens mounted thereon.

6. An optical module comprising:
an optical semiconductor device chip;
a stem having the optical semiconductor device chip mounted thereon; and
a lens holder arranged for containing the optical semiconductor device chip therein and having an optical fiber ferrule connected to one end of the lens holder,
wherein the lens holder is resistance-welded to the stem using a welding part structure of the stem and the lens holder, the welding part structure including a high and tapered projection provided at the other end of the lens holder and a small protrusion provided inside the projection and having a height lower than that of the projection.

7. A manufacturing method of a semiconductor device comprising the steps of:
preparing a welding part structure including a high and tapered projection provided on the upper surface of a stem having a semiconductor device chip mounted thereon or on the bottom surface of a cap arranged for surrounding the semiconductor device chip and a low and small protrusion provided inside the projection; and
resistance-welding the cap to the stem.

8. The manufacturing method of a semiconductor device according to claim 7, wherein the semiconductor device chip is an optical semiconductor device chip while the cap includes a lens mounted thereon, and the cap is resistance-welded to the stem.

9. A manufacturing method of an optical module comprising the steps of
preparing a welding part structure including a high and tapered projection provided on the upper surface of a stem having an optical semiconductor device chip mounted thereon or on the bottom surface of a lens holder arranged for surrounding the optical semiconductor device chip, one end of the lens holder being capable of connecting an optical fiber ferrule, and a low and small protrusion provided inside the projection; and
resistance-welding the lens holder to the stem.

10. The welding part structure according to claim 1, wherein the small protrusion is provided with an insulation film formed on the bottom surface of the small protrusion.

11. The welding part structure according to claim 2, wherein the small protrusion is provided with an insulation film formed on the bottom surface of the small protrusion.

12. The welding part structure according to claim 3, wherein the small protrusion is provided with an insulation film formed on the bottom surface of the small protrusion.

13. The semiconductor device according to claim 4, wherein the small protrusion is provided with an insulation film formed on the bottom surface of the small protrusion.

14. The semiconductor device according to claim 5, wherein the small protrusion is provided with an insulation film formed on the bottom surface of the small protrusion.

15. The optical module according to claim 6, wherein the small protrusion is provided with an insulation film formed on the bottom surface of the small protrusion.

16. The manufacturing method of a semiconductor device according to claim 7, wherein the small protrusion is provided with an insulation film formed on the bottom surface of the small protrusion.

17. The manufacturing method of a semiconductor device according to claim 8, wherein the small protrusion is provided with an insulation film formed on the bottom surface of the small protrusion.

18. The manufacturing method of an optical module according to claim 9, wherein the small protrusion is provided with an insulation film formed on the bottom surface of the small protrusion.
